(19) United States
(12) Patent Application Publication
(10) Pub. No.: US 2006/0003594 A1
(43) Pub. Date: Jan. 5, 2006

(54) Molecules for langmuir-blodgett deposition of a molecular layer

(76) Inventors: Sean X. Zhang, Sunnyvale, CA (US); Douglas A. A. Ohlberg, Mountain View, CA (US); Zhiyong Li, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/881,681

(22) Filed: Jun. 30, 2004

(51) Int. Cl. H01L 21/31; H01L 21/469

(52) U.S. Cl. 438/758

(57) ABSTRACT

A molecule for Langmuir-Blodgett (LB) deposition of a molecular layer. The molecule includes at least one switching moiety, a hydrophilicity-modifiable connecting group attached to one end of the moiety, and a hydrophilicity-non-modifiable connecting group attached to the other end of the moiety. The hydrophilicity-modifiable connecting group is transformable to a temporary end group upon adjustment in pH of the aqueous environment containing the molecule. The temporary end group is more hydrophilic than the hydrophilicity-modifiable connecting group and the hydrophilicity-non-modifiable connecting group. The difference in hydrophilicity between the temporary end group and the hydrophilicity-non-modifiable connecting group causes formation of a substantially well-oriented, uniform LB film at a water/solvent and/or water/air interface.

### BACKGROUND

The present disclosure relates generally to molecular electronics, and more particularly to molecular layers formed using Langmuir-Blodgett methods.

Molecular devices having two electrodes (for example, a bottom electrode and a top electrode) and a molecular switching layer or film at the junction of the two electrodes are known. Such devices may be useful, for example, in the fabrication of devices based on electrical switching, such as molecular wire crossbar interconnects for signal routing and communications, molecular wire crossbar memory, molecular wire crossbar logic employing programmable logic arrays, multiplexers or demultiplexers for molecular wire crossbar networks, molecular wire transistors, and the like. Such devices may further be useful, for example, in the fabrication of devices based on optical switching, such as displays, electronic books, rewritable media, electrically tunable optical lenses, electrically controlled tinting for windows and mirrors, optical crossbar switches (for example, for routing signals from one of many incoming channels to one of many outgoing channels), and the like.

Typically, the molecular switching layer or film has an organic molecule that, in the presence of an electrical (E) field, switches between two or more energetic states, such as by an electro-chemical oxidation or reduction (redox) reaction or by a change in the band gap of the molecule induced by the applied E-field.

It is important to form a good electrical contact between the electrode and the molecular switching layer in order to fabricate operative molecular devices. Molecules with special chemical end groups are able to form direct chemical bonds with metal or semiconductor electrodes to form a self-assembled monolayer (SAM), which may have a good electrical contact with an electrode(s). However, this self-assembled molecular layer formed on the surface of the electrode may generally be prone to a high density of defects. If a second electrode is formed on the molecular layer, then an electrical short may occur between the first and second electrode through the defects in the self-assembled molecular layer.

The formation of Langmuir-Blodgett (LB) layers or films employing switching molecules has been attempted because such layers or films are generally much denser than SAM films. Further, LB layers or films have relatively low defect densities compared to SAM films. However, it has proven to be a significant challenge to effectively bond LB films to the electrode substrate. As such, if the LB film is not sufficiently bonded to the electrode(s), then poor electrical contact may result.

As such, there is a need for providing a high density molecular switching layer on an electrode(s), which layer also bonds well with the electrode.

### SUMMARY

A molecule for Langmuir-Blodgett (LB) deposition of a molecular layer is disclosed. The molecule includes at least one switching moiety, a hydrophilicity-modifiable connecting group attached to one end of the moiety, and a hydrophilicity-non-modifiable connecting group attached to the other end of the moiety. The hydrophilicity-modifiable connecting group is transformable to a temporary end group upon adjustment in pH of the aqueous environment containing the molecule. The temporary end group is more hydrophilic than the hydrophilicity-modifiable connecting group and the hydrophilicity-non-modifiable connecting group. The difference in hydrophilicity between the temporary end group and the hydrophilicity-non-modifiable connecting group causes formation of a substantially well-oriented, uniform LB film at a solvent surface.

### BRIEF DESCRIPTION OF THE DRAWINGS

Objects, features and advantages will become apparent by reference to the following detailed description and drawings, in which like reference numerals correspond to similar, though not necessarily identical components. For the sake of brevity, reference numerals having a previously described function may not necessarily be described in connection with subsequent drawings in which they appear.

FIG. 1A is a schematic representation of two crossed wires, with at least one molecule at the intersection of the two wires;

FIG. 1B is a perspective elevational view, depicting the crossed-wire device shown in FIG. 1a;

FIG. 2 is a schematic representation of a two-dimensional array of switches, depicting a 6×6 crossbar switch;

FIGS. 3A-3D is a schematic flow diagram depicting an embodiment of a method of the present invention;

FIGS. 4A-4D is similar to FIG. 3, but depicts an alternate embodiment of a method of the present invention; and

FIGS. 5A-5B is similar to FIG. 3, but depicts yet a further alternate embodiment of a method of the present invention.

### DETAILED DESCRIPTION OF THE EMBODIMENTS

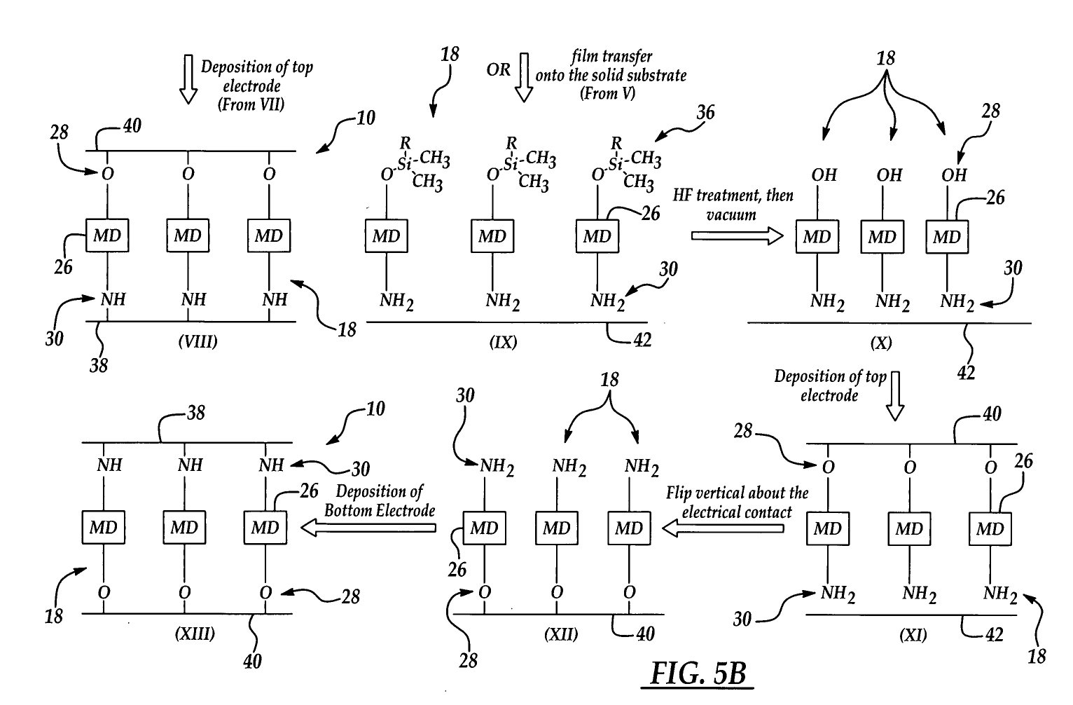

Embodiments of the present invention advantageously use a novel concept of hydrophilicity modification. This concept takes advantage of the advantageous qualities of self-assembly techniques (e.g. good electrical contact due to chemical bonding) and Langmuir-Blodgett (LB) deposition (e.g. low defect density). The concept further substantially eliminates problems that may in some instances be associated with both methods. The method according to embodiments of the present invention provides a good Langmuir-Blodgett film(s), orienting the connecting groups at the ends of the molecule forming the film(s), such that chemical bonding and the formation of good electrical contact with the crossbar electrodes at either end of the molecule is promoted (described in further detail below, also for example with reference to FIGS. 5A-5B).

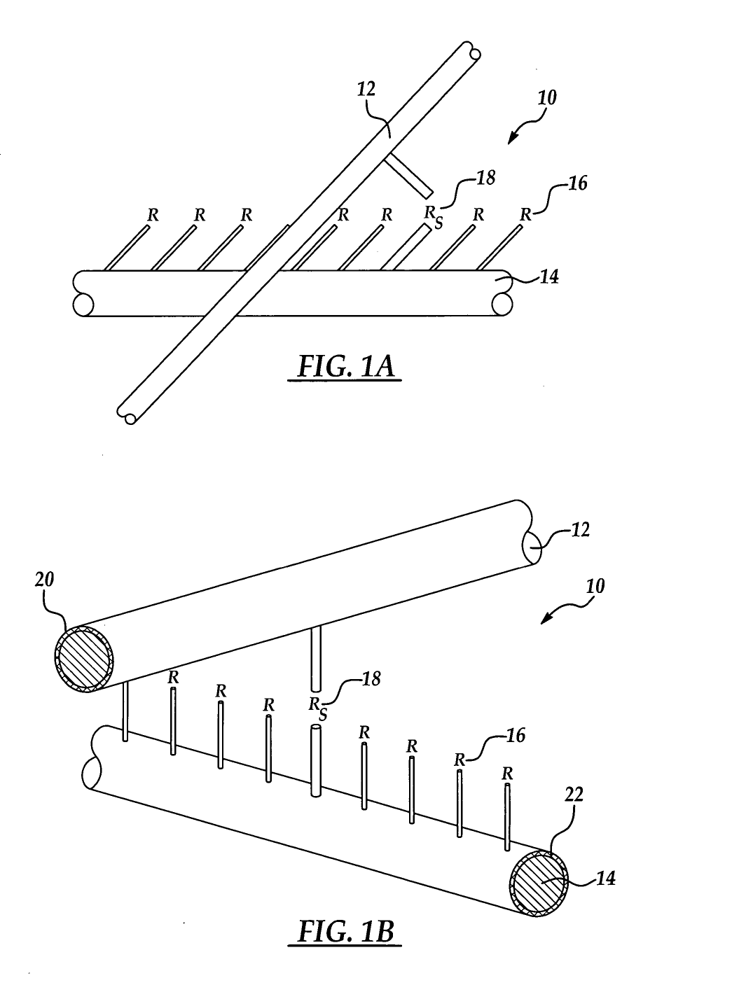

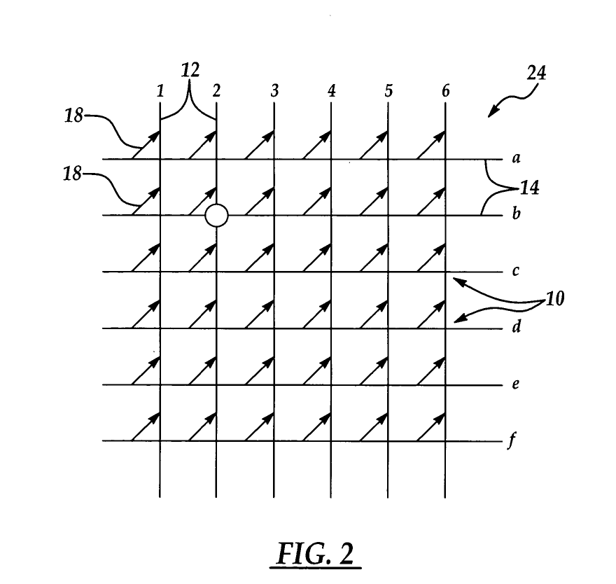

Referring now to FIGS. 1A-1B, a crossed wire switching device 10 includes two wires 12, 14, each either a metal or semiconductor wire, that are crossed at some substantially non-zero angle. Disposed between wires 12, 14 is a layer 16 of molecules, molecular compounds, or mixtures thereof, denoted R. The particular molecules 18 that are sandwiched at the intersection (also interchangeably referred to herein as a junction) of the two wires 12, 14 are identified as switch molecules R_{S}.

There are generally two primary methods of operating such switches 10, depending on the nature of the switch molecules 18. The molecular switching layer 16 includes a switch molecule 18 (for example, an organic molecule) that, in the presence of an electrical (E) field, switches between two or more energetic states, such as by an electrochemical oxidation or reduction (redox) reaction or by a change in the band gap of the molecule induced by the applied E-field.

In the former case, when an appropriate voltage is applied across the wires 12, 14, the switch molecules R_{S} are either oxidized or reduced. When a molecule is oxidized (reduced), then a second species is reduced (oxidized) so that charge is balanced. These two species are then called a redox pair. One example of this device would be for one molecule to be reduced, and then a second molecule (the other half of the redox pair) would be oxidized. In another example, a molecule is reduced, and one of the wires 12, 14 is oxidized. In a third example, a molecule is oxidized, and one of the wires 12, 14 is reduced. In a fourth example, one wire 12, 14 is oxidized, and an oxide associated with the other wire 14, 12 is reduced. In such cases, oxidation or reduction may affect the tunneling distance or the tunneling barrier height between the two wires, thereby exponentially altering the rate of charge transport across the wire junction, and serving as the basis for a switch. Examples of molecules 18 that exhibit such redox behavior include rotaxanes, pseudo-rotaxanes, and catenanes; see, e.g., U.S. Pat. No. 6,459,095, entitled “Chemically Synthesized and Assembled Electronic Devices”, issued Oct. 1, 2002, to James R. Heath et al, the disclosure of which is incorporated herein by reference in its entirety.

Further, the wires 12, 14 may be modulation-doped by coating their surfaces with appropriate molecules—either electron-withdrawing groups (Lewis acids, such as boron trifluoride (BF₃)) or electron-donating groups (Lewis bases, such as alkylamines) to make them p-type or n-type conductors, respectively. FIG. 1B depicts a coating 20 on wire 12 and a coating 22 on wire 14. The coatings 20, 22 may be modulation-doping coatings, tunneling barriers (e.g., oxides), or other nano-scale functionally suitable materials. Alternatively, the wires 12, 14 themselves may be coated with one or more R species 16, and where the wires cross, R_{S} 18 is formed. Or yet alternatively, the wires 12, 14 may be coated with molecular species 20, 22, respectively, for example, that enable one or both wires to be suspended to form colloidal suspensions, as discussed below. Details of such coatings are provided in above-referenced U.S. Pat. No. 6,459,095.

In the latter case, examples of molecule 18 based on field induced changes include E-field induced band gap changes, such as disclosed and claimed in patent application Ser. No. 09/823,195, filed Mar. 29, 2001, published as Publication No. 2002/0176276 on Nov. 28, 2002, which application is incorporated herein by reference in its entirety. Examples of molecules used in the E-field induced band gap change approach include molecules that evidence molecular conformation change or an isomerization; change of extended conjugation via chemical bonding change to change the band gap; or molecular folding or stretching.

Changing of extended conjugation via chemical bonding change to change the band gap may be accomplished in one of the following ways: charge separation or recombination accompanied by increasing or decreasing band localization; or change of extended conjugation via charge separation or recombination and π-bond breaking or formation.

The formation of micrometer scale and nanometer scale crossed wire switches 10 uses either a reduction-oxidation (redox) reaction to form an electrochemical cell or uses E-field induced band gap changes to form molecular switches. In either case, the molecular switches typically have two states, and may be either irreversibly switched from a first state to a second state or reversibly switched from a first state to a second state. In the latter case, there are two possible conditions: either the electric field may be removed after switching into a given state, and the molecule will remain in that state (“latched”) until a reverse field is applied to switch the molecule back to its previous state; or removal of the electric field causes the molecule to revert to its previous state, and hence the field must be maintained in order to keep the molecule in the switched state until it is desired to switch the molecule to its previous state.

Color switch molecular analogs, particularly based on E-field induced band gap changes, are also known; see, e.g., U.S. application Ser. No. 09/844,862, filed Apr. 27, 2001.

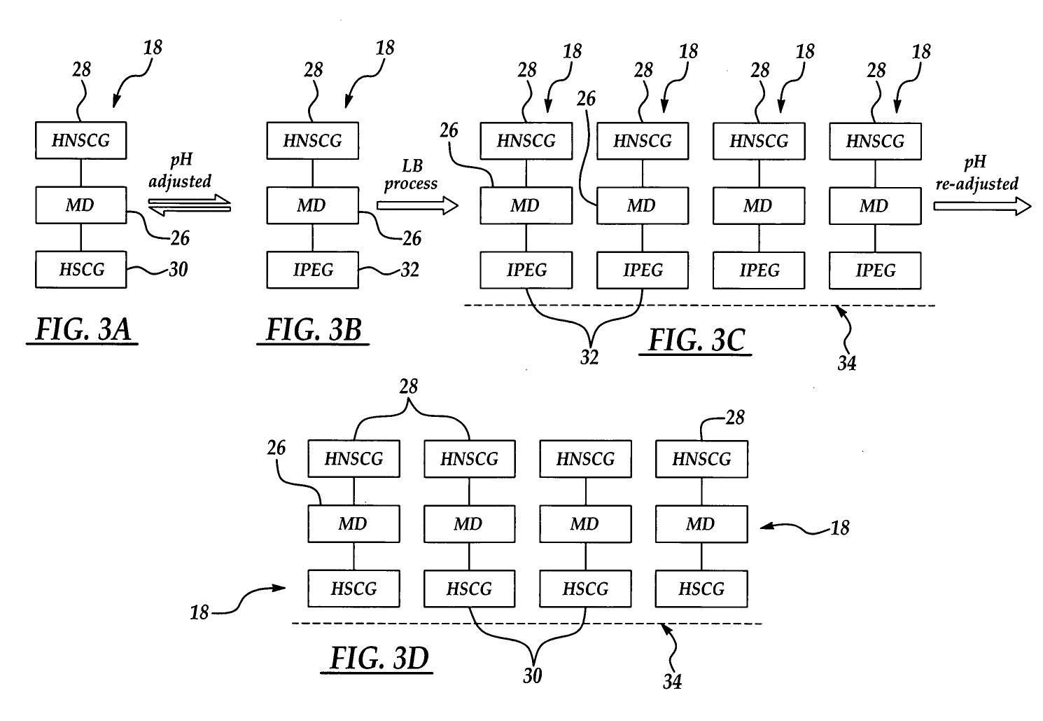

Referring now to FIG. 2, the switch 10 may be replicated in a two-dimensional array to form a plurality or array 24 of switches 10 to form a crossbar switch. FIG. 2 depicts a 6×6 array 24. However, it is to be understood that the embodiments herein are not to be limited to the particular number of elements, or switches 10, in the array 24. Access to a single point, e.g., 2b, is done by impressing voltage on wires 2 and b to cause a change in the state of the molecular species 18 at the junction thereof, as described above. Thus, access to each junction is readily available for configuring those that are pre-selected. Details of the operation of the crossbar switch array 24 are further discussed in U.S. Pat. No. 6,128,214, entitled “Molecular Wire Crossbar Memory”, issued on Oct. 3, 2000, to Philip J. Kuekes et al., which is incorporated herein by reference in its entirety.

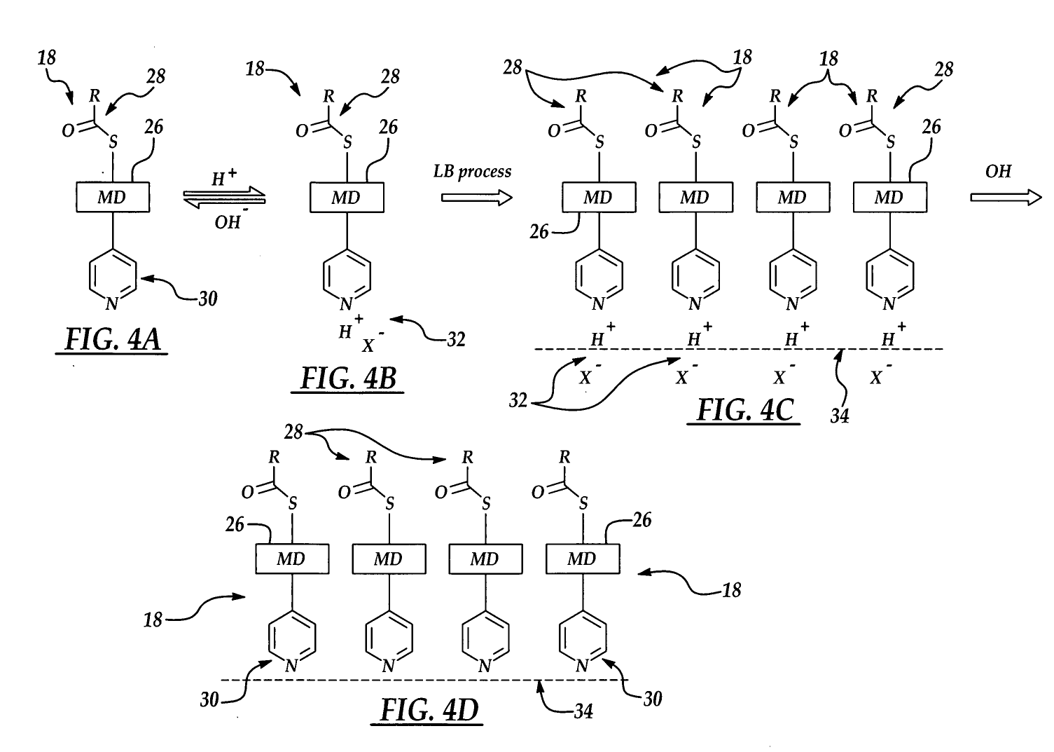

FIG. 3A depicts an embodiment of a molecule suitable to form a molecular layer(s) attachable to a substrate. An aqueous environment contains a molecule 18 with a molecular switching moiety (MD) 26 having a hydrophilicity-modifiable connecting group (HSCG) 30 attached to one end of the moiety 26, and a hydrophilicity-non-modifiable connecting group (HNSCG) 28 attached to an opposed end of the moiety 26.

In an embodiment of the present invention, the molecule 18 is an organic molecule, and the molecular switching moiety 26 is an optically switchable molecular functional unit or an electrically switchable molecular functional unit. It is to be understood that the switching moiety 26 may be any suitable moiety, however, in an embodiment, the moiety 26 includes at least one of saturated hydrocarbons, unsaturated hydrocarbons, substituted hydrocarbons, heterocyclic systems, organometallic complex systems, or mixtures thereof.

In an embodiment, the switching moiety 26 is a moiety that, in the presence of an electric field, undergoes at least one of oxidation or reduction, and/or experiences a band gap change. In one embodiment, the switching moiety 26 undergoes at least one of oxidation or reduction and is at least one of rotaxanes, pseudo-rotaxanes, catenanes, and mixtures thereof. An example of a switching moiety 26 that undergoes a band gap change in the presence of an external electrical field is described in U.S. Pat. No. 6,674,932 granted to Zhang et al. on Jan. 6, 2004, the specification of which is incorporated herein by reference in its entirety.

It is to be understood that any suitable hydrophilicity-non-modifiable connecting group (HNSCG) 28 may be used as desired or necessitated by a particular end use. In an embodiment of the present invention, the hydrophilicity-non-modifiable connecting group (HNSCG) 28 is at least one of multivalent hetero atoms selected from the group consisting of C, N, O, S, and P; functional groups containing the hetero atoms and selected from the group consisting of SH, OH, SiCl₃, NH, and PH; saturated hydrocarbons; unsaturated hydrocarbons; substituted hydrocarbons; heterocyclic compounds; carboxylic acids; derivatives thereof (non-limitative examples of which include carboxylic esters, amides, nitrites, or the like); and mixtures thereof.

In a further embodiment of the present invention, the hydrophilicity-non-modifiable connecting group (HNSCG) 28 functional groups are at least one of S-alkyl, S-aryl, S—S-alkyl, S—S-aryl, S-acyl, O-aryl, O-alkyl, O-acyl, NH₂, NH-alkyl, NH-aryl, NH-acyl, N-(alkyl)₂, N-(aryl)₂, N-(alkyl)(aryl), PH₂, PH-alkyl, PH-aryl, PH-acyl, P-(alkyl)₂, P-(aryl)₂, P-(alkyl)(aryl), and mixtures thereof.

It is to be understood that any suitable hydrophilicity-modifiable connecting group (HSCG) 30 may be used as desired or necessitated by a particular end use. In an embodiment of the present invention, the hydrophilicity-modifiable connecting group (HSCG) 30 is at least one of multivalent hetero atoms selected from the group consisting of C, N, O, S, and P; functional groups containing the hetero atoms and selected from the group consisting of SH, OH, SiCl₃, NH, and PH; saturated hydrocarbons; unsaturated hydrocarbons; substituted hydrocarbons; heterocyclic compounds; carboxylic acids; derivatives thereof; and mixtures thereof.

In a further embodiment of the present invention, the hydrophilicity-modifiable connecting group (HSCG) 30 functional groups are at least one of NH₂, NH-alkyl, NH-aryl, N-(alkyl)₂, N-(aryl)₂, N-(alkyl)(aryl), PH₂, PH-alkyl, PH-aryl, P-(alkyl)₂, P-(aryl)₂, P-(alkyl)(aryl), pyridine, and mixtures thereof.

Referring now to FIG. 3B, as the pH of the aqueous environment is adjusted, the hydrophilicity-modifiable connecting group (HSCG) 30 is transformed into a temporary end group (IPEG) 32, wherein the temporary end group 32 is more hydrophilic than the hydrophilicity-modifiable connecting group (HSCG) 30 and the hydrophilicity-non-modifiable connecting group (HNSCG) 28.

Referring now to FIG. 3C, a Langmuir-Blodgett (LB) film of the molecule 18 is formed on an interface 34 between an organic solvent(s)/air and water, the film being depicted by the plurality of molecules 18 shown. The organic solvent(s) is above the water, and in some instances may volatilize quickly; as such what was an interface 34 between water and organic solvent(s) may become an interface 34 between water and air. Thus, it is to be understood that interface 34 as defined herein may be a water/solvent interface 34 and/or a water/air interface 34. Without being bound to any theory, it is believed that the difference in hydrophilicity between the temporary end group 32 and the hydrophilicity-non-modifiable connecting group 28 causes formation of a substantially well-oriented, uniform LB film at the interface 34 of the organic solvent(s)/air and the water.

The pH of the aqueous environment is then re-adjusted so as to transform the temporary end group 32 back to the hydrophilicity-modifiable connecting group 30, as shown in FIG. 3D. The substrate is then passed through the Langmuir-Blodgett film to form the molecular layer chemically bonded on the substrate (not shown in FIGS. 3A-3D).

Embodiments of the present invention are advantageously suitable for fabricating molecular devices with molecules containing two or more substantially asymmetric, connecting end-groups 28, 30. In an embodiment, it is desirable that both of the connecting end-groups 28, 30 be capable of forming good electrical contact with electrodes 38, 40 (as shown in FIGS. 5A and 5B) made of noble metals (e.g. Au, Pt, Ag, Cu, alloys of these metals, or the like) via chemical bonding.

In an embodiment, one of the hydrophilicity-modifiable connecting group 30 or the hydrophilicity-non-modifiable connecting group 28 is a connecting unit between the organic molecule 18 and the substrate (38, 40, 42 as shown in FIGS. 5A and 5B). The other of the hydrophilicity-modifiable connecting group 30 or the hydrophilicity-non-modifiable connecting group 28 is a connecting unit between the organic molecule 18 and an other substrate (38, 40, 42 as shown in FIGS. 5A and 5B). It is to be understood that the substrate and the other substrate is a solid substrate, and may be either an electrode or a non-electrode, depending on the application. It is to be further understood that the substrate and the other substrate may each be hydrophilic, hydrophobic, or one may be hydrophilic and the other may be hydrophobic. As such, connecting group 30 or connecting group 28 will be more attracted to the substrate or other substrate, depending upon the hydrophilicity/hydrophobicity of the substrate or other substrate and of the group 30, 28. The substrates will be discussed in further detail below in relation to FIGS. 5A and 5B.

The method of the embodiment outlined above will be discussed in more detail herein. The hydrophilicity of one of the end groups 30 may be modified by changing the pH of the aqueous environment, for example the subphase of an LB trough, within a range under which the other end group 28 of the molecule 18 remains inert. This change in hydrophilicity of the one end group 30 is due to the formation of a temporary end group 32 following the pH adjustment. It is to be understood that the temporary end group 32 may be any suitable end group. However, in an embodiment, the temporary end group 32 is an ion pair (IPEG) 32. It is to be further understood that the ion pair 32 may be any suitable ion pair. A non-limitative example of such an ion pair 32 is H⁺X⁻, wherein X— is at least one of Br⁻, Cl⁻, I⁻, CH₃CO₂⁻, HCO₂⁻, NO₃⁻, H₂PO₄⁻, HPO₄²⁻, HSO₄⁻, SO₄²⁻, other organic acids, or mixtures thereof.

The conversion of the one end-group 30 to an ion pair 32 makes it more hydrophilic than the inert end-group 28, causing the molecule to orient itself such that the ion pair (temporary end group) 32 preferentially resides at the solvent/water interface 34 of the LB trough. After forming this film, the pH of the subphase in the LB trough is then carefully readjusted. The pH change converts the ion pair 32 at the solvent-air interface 34 back to the original reactive end-group 30 for a subsequent bonding reaction with the metal electrodes 38, 40.

It is to be understood that any solvent suitable for an LB process may be used. In an embodiment, the solvent is water, organic solvents, or mixtures thereof. Suitable organic solvents include, but are not limited to chloroform, dichloromethane, benzene, toluene, ethyl acetate, hexane, pentane, heptane, ethyl ether, or the like.

In carrying out embodiments of the method, it is desirable to consider the following guidelines. The hydrophilicity-modifiable connecting group (HSCG) 30 may be sensitive to pH changes; whereas the hydrophilicity-non-modifiable connecting group (HNSCG) 28 may be substantially inert to pH change. It would be desirable that both the hydrophilicity-modifiable connecting group (HSCG) 30 and the hydrophilicity-non-modifiable connecting group (HNSCG) 28 be reactive enough to react with a noble metal electrode substrate to form a stable chemical bond. It would be desirable that both the hydrophilicity-modifiable connecting group (HSCG) 30 and the hydrophilicity-non-modifiable connecting group (HNSCG) 28 be substantially hydrophobic, but soluble in selected organic solvents. It is desirable that the molecular switching moiety (MD) 26 be stable to pH change and substantially hydrophobic. Further, the LB process and thin film transfer may desirably be carried out in a substantially inert atmosphere to aid in preventing the highly reactive connecting end-groups 28, 30 from being deleteriously affected or destroyed by oxidation.

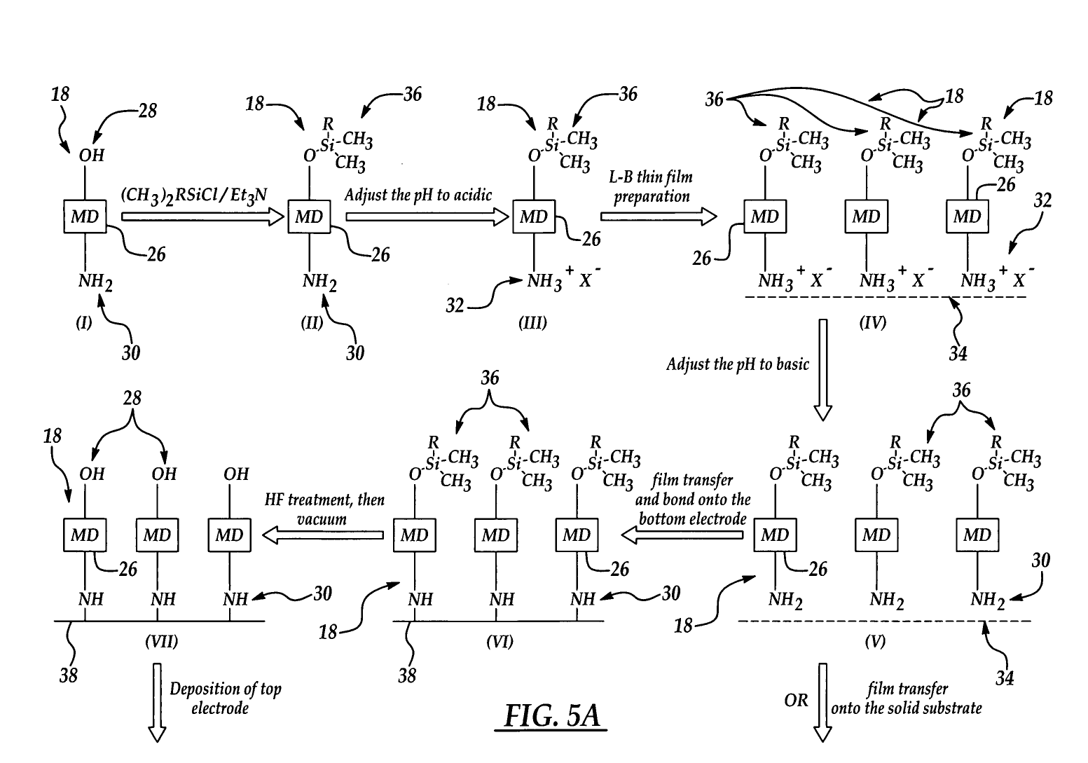

A non-limitative embodiment is shown in FIGS. 4A-4D. In this embodiment, the hydrophilicity-non-modifiable connecting group (HNSCG) 28 is an S—COR group, and the hydrophilicity-modifiable connecting group (HSCG) 30 is a pyridine group. Both of these end-groups 28, 30 are very reactive towards the noble metals (e.g. Au, Cu, Ag, Pt, alloys of these metals, or the like) and are able to form good chemical bonds to these metals. The pyridine group is a mild base, which may be protonated under a weakly acidic environment (pH greater than about 5), and the S—COR is a neutral unit that is stable under pH regimes ranging from about pH 4 to about pH 9. The letter R designates any suitable hydrophobic end-group. In an embodiment, R may be selected from any alkyl group, aryl group, or combinations thereof. Some examples of suitable R groups include, but are not limited to CH₃, C₂H₅—, C₃H₇—, C₆H₅—, C₆H₅—CH₂—, or the like.

After carefully adjusting the pH of the water solution in the LB trough, an ion pair H⁺X⁻ is formed at the pyridine end-group 32. The formation of the ion pair H⁺X⁻ greatly enhances the hydrophilicity of the pyridine end-group 32, tethering it more strongly to the air-water interface than the S—COR end-group 28, thereby resulting in a preferential orientation of the molecules 18 that helps to form a good, substantially uniform LB thin film.

After this good, substantially uniform thin film is formed in the LB trough, the pH environment of the LB trough is carefully readjusted. The pH change converts the ion pair H⁺X⁻ back to the non-protonated pyridine end-group 30 that is able to chemically bond with metal electrodes (not shown in FIGS. 4A-4D).

A further non-limitative embodiment is shown in FIGS. 5A-5B. In this embodiment, as shown in FIG. 5A(I), an OH group is the hydrophilicity-non-modifiable connecting group (HNSCG) 28 and an NH₂ group is the hydrophilicity-modifiable connecting group (HSCG) 30 of the molecule 18. Both of these groups 28, 30 are reactive toward the noble metals (e.g. Au, Cu, Ag, Pt, etc), and are able to form good chemical bonding with electrode material.

The —OSi(CH3)₂R group is an example of a trialkyl silyl type of hydrophobic temporary protecting group 36 (one non-limitative example of a temporary protecting group 36) generated by treating —OH with (CH3)₂RSiCl under a mild base condition (Et₃N) to form a mono-capped molecule (see FIG. 5A(II)). This group 36 is stable during the preparation of the X⁻NH3⁺ ion pair (the water soluble cationic form of the —NH₂ group) temporary end group 32, and during the L-B thin film preparation process (see FIGS. 5A(III) and 5A(IV)). It is to be understood that the temporary protecting group 36 may be hydrophobic or hydrophilic, as desired or necessitated by a particular embodiment(s). The highly water-soluble X⁻NH₃₊ ion pair is generated from the —NH₂ group by carefully adjusting the pH to acidic (pH ranging between about 2 and about 4). This ion pair on the temporary end group 32 will help the end group 32 stay in the interface 34 of water and organic solvent during the Langmuir-Blodgett monolayer thin film preparation (which, as stated hereinabove, enables preparation of a high quality LB thin film). Further, the temporary end group 32 will be stable during the LB thin film preparation.

It is to be understood that R in the temporary protecting group 36 may be any suitable alkyl group, including, but not limited to, —CH₃, —C₂H₅, —C₃H₇, —C₄H₉, —C₅H₁₁, —C₆H₁₃, —C₇H₁₅, —C₈H₁₇, —C₉H₁₉, —C₁₀H₂₁, —C₁₁H₂₃, substituted hydrocarbons (e.g. —(CH₂)ₙ—Ar; —(CH₂)ₙ-Het; where n>0, the —Ar may be any suitable aromatic hydrocarbon, and the Het may be any suitable heterocyclic system; or the like), or combinations thereof. A generic representation of a trialkyl silyl type of temporary protecting group 36 is —OSiR₁R₂R₃. It is to be understood that the R₁, R₂, R₃ may each be the same type of alkyl group, may each be a different alkyl group, or may be any combination of similar and different alkyl groups. The non-limitative examples of R groups listed above may also serve as suitable non-limitative examples of R₁, R₂, R₃ groups.

The temporary protecting group 36 may also advantageously aid in orienting the molecule 18 such that the temporary protecting group 36 remains in the air, and the ion pair end group 32 remains at the water/solvent interface 34.

Referring now to FIGS. 5A(IV) and 5A(V), the highly water-soluble X⁻NH₃⁺ ion pair may be selectively reconverted back to —NH₂ by carefully readjusting the pH of the water phase to basic (for example, a pH greater than about 10) with a sodium hydroxide (NaOH) solution after the thin film is formed.

In any of the embodiments described herein, there are at least two non-limitative embodiments for constructing crossbar devices 10 with good electrical contact. A first embodiment, direct linking to the electrode substrate, may be desirable if the end-group 30 is reactive enough to form a chemical bond quickly with the bottom electrode 38 (it is to be understood that an annealing at a mild elevated temperature under an inert environment may be advantageous in order to facilitate the solid-solid interaction).

In this first embodiment, the L-B thin film (FIG. 5A(V)) is transferred and chemically bonded onto the bottom electrode 38 to form a semi-device (FIG. 5A(VI)). At this time, the protecting group 36 may be removed by a treatment with hydrofluoric acid (HF), followed by vacuum evaporation of volatile by-products to render a complete un-protected semi-device (FIG. 5A(VII)). A chemically bonded top metal electrode 40 may then be formed by, for example, a sputtering process or an evaporative metal deposition process to yield the desired crossbar device 10 (FIG. 5B(VIII)).

A second non-limitative embodiment for constructing crossbar devices 10 with good electrical contact may be desirable if the end-group 30 is not reactive enough toward the electrode substrate 38 in the bonding reaction among the solid-solid interface. In this second embodiment, the LB thin film (FIG. 5A(V)) is transferred onto a non-electrode solid substrate 42 to form a temporary intermediate device (FIG. 5B(IX)). At this time, the protecting group 36 may be removed by a treatment with hydrofluoric acid (HF), followed by vacuum evaporation of volatile by-products to render an uncapped molecule 18 (FIG. 5B(X)). A chemically bonded top metal electrode 40 is then formed by an evaporative metal deposition, a sputtering process, or the like to yield a semi-device (FIG. 5B(XI)). The device is then flipped vertically about the electrical contact to yield the device as shown in FIG. 5B(XII). Non-electrode solid substrate 42 is removed, and a bottom electrode 38 is then formed by an evaporative metal deposition process, a sputtering process, or the like to finish the final desired crossbar device 10 (FIG. 5B(XIII)).

It is to be understood that non-electrode solid substrate 42 may be formed from any suitable material, including but not limited to at least one of inorganic materials (e.g. glass, silicon, metal oxides (e.g. silicon oxides, aluminum oxides, etc.) and the like), organic materials (e.g. polycarbonates and the like), or combinations thereof.

An embodiment of a crossed wire molecular device 10 includes a plurality of bottom electrodes 38, a plurality of top electrodes 40 crossing the bottom electrodes 38 at a non-zero angle, and a molecular layer formed from a plurality of organic molecules 18, each of the molecules 18 having at least one molecular switching moiety 26. The molecular layer is operatively disposed in at least one junction formed where one electrode 38, 40 crosses another electrode 40, 38. A non-limitative embodiment of a method of forming the crossed wire molecular device 10 is as follows. The pH of the aqueous environment is adjusted as described hereinabove in a manner sufficient to transform the hydrophilicity-modifiable connecting group 30 to a temporary end group 32. A Langmuir-Blodgett (LB) film of the molecule 18 is formed on the solvent/water interface 34. The pH is re-adjusted in a manner sufficient to transform the temporary end group 32 back to the hydrophilicity-modifiable connecting group 30. Each of the plurality of bottom electrodes 38 is passed through the Langmuir-Blodgett film to form the molecular layer chemically bonded, via the hydrophilicity-modifiable connecting group 30, on a surface of the bottom electrode 38. The method may further include forming one of the plurality of top electrodes 40, crossing the one of the plurality of bottom electrodes 38 at the non-zero angle, thereby forming the junction therebetween. The molecular layer is thereby chemically bonded, via the hydrophilicity-non-modifiable connecting group 28, on a surface of the top electrode.

While several embodiments have been described in detail, it will be apparent to those skilled in the art that the disclosed embodiments may be modified. Therefore, the foregoing description is to be considered exemplary rather than limiting.

What is claimed is:

1. A method of attaching a molecular layer to a substrate, the method comprising:
adjusting pH of an aqueous environment comprising a molecule with a molecular switching moiety having a hydrophilicity-modifiable connecting group attached to one end of the moiety, and a hydrophilicity-non-modifiable connecting group attached to an opposed end of the moiety, the pH adjusting thereby transforming the hydrophilicity-modifiable connecting group to a temporary end group, wherein the temporary end group is more hydrophilic than the hydrophilicity-modifiable connecting group and the hydrophilicity-non-modifiable connecting group;
forming a Langmuir-Blodgett (LB) film of the molecule on at least one of a water/solvent interface and a water/air interface;
re-adjusting the pH of the aqueous environment so as to transform the temporary end group back to the hydrophilicity-modifiable connecting group; and
passing the substrate through the Langmuir-Blodgett film to form the molecular layer chemically bonded on the substrate;
wherein the difference in hydrophilicity between the temporary end group and the hydrophilicity-non-modifiable connecting group causes formation of a substantially well-oriented, uniform LB film at the at least one of the water/solvent interface and the water/air interface.

2. The method as defined in claim 1 wherein the temporary end group orients the molecule such that the temporary end group preferentially resides at the at least one of the water/solvent interface and the water/air interface during the LB film formation.

3. The method as defined in claim 1 wherein the temporary end group is an ion pair.

4. The method as defined in claim 3 wherein the ion pair comprises H⁺X⁻, wherein X— is at least one of Br⁻, Cl⁻, I⁻, CH₃CO₂⁻, HCO₂⁻, NO₃⁻, H₂PO₄⁻, HPO₄²⁻, HSO₄⁻, SO₄²⁻, other organic acids, and mixtures thereof.

5. The method as defined in claim 1 wherein the solvent is at least one of water, organic solvents, and mixtures thereof.

6. The method as defined in claim 1 wherein the molecule is an organic molecule and wherein the molecular switching moiety is at least one of an optically switchable molecular functional unit and an electrically switchable molecular functional unit.

7. The method as defined in claim 6 wherein the molecular switching moiety comprises saturated hydrocarbons, unsaturated hydrocarbons, substituted hydrocarbons, heterocyclic systems, organometallic complex systems, and mixtures thereof.

8. The method as defined in claim 6 wherein the switching moiety comprises at least one of a moiety that, in the presence of an electric field, undergoes at least one of oxidation and reduction; and a moiety that, in the presence of an electric field, experiences a band gap change.

9. The method as defined in claim 8 wherein the switching moiety undergoes at least one of oxidation and reduction and comprises at least one of rotaxanes, pseudo-rotaxanes, catenanes, and mixtures thereof.

10. The method as defined in claim 8 wherein the switching moiety experiences a band gap change of a type comprising:
at least one of molecular conformation change and an isomerization;
change of extended conjugation via chemical bonding change to change the band gap;
at least one of molecular folding and stretching; and
combinations thereof.

11. The method as defined in claim 10 wherein the changing of extended conjugation via chemical bonding change to change the band gap is accomplished by at least one of:
charge separation or recombination accompanied by increasing or decreasing band localization; and
change of extended conjugation via charge separation or recombination and π-bond breaking or formation.

12. The method as defined in claim 6 wherein one of the hydrophilicity-modifiable connecting group and the hydrophilicity-non-modifiable connecting group is a connecting unit between the organic molecule and the substrate, and wherein the other of the hydrophilicity-non-modifiable connecting group and the hydrophilicity-modifiable connecting group is a connecting unit between the organic molecule and an other substrate.

13. The method as defined in claim 12 wherein at least one of the substrate and the other substrate comprises an electrode of a crossed-wire device.

14. The method as defined in claim 13 wherein the electrode comprises at least one of a bottom electrode and a top electrode.

15. The method as defined in claim 13 wherein the hydrophilicity-modifiable connecting group is a connecting unit between the organic molecule and the substrate, and wherein the substrate is a bottom electrode.

16. The method as defined in claim 15 wherein the hydrophilicity-non-modifiable connecting group is a connecting unit between the organic molecule and the other substrate, and wherein the other substrate is a top electrode.

17. The method as defined in claim 1 wherein the hydrophilicity-non-modifiable connecting group comprises at least one of multivalent hetero atoms selected from the group consisting of C, N, O, S, and P; functional groups containing the hetero atoms and selected from the group consisting of SH, OH, SiCl₃, NH, and PH; saturated hydrocarbons; unsaturated hydrocarbons; substituted hydrocarbons; heterocyclic compounds; carboxylic acids; carboxylic esters; amides; nitriles; and mixtures thereof.

18. The method as defined in claim 17 wherein the hydrophilicity-non-modifiable connecting group functional groups comprise at least one of S-alkyl, S-aryl, S—S-alkyl, S—S-aryl, S-acyl, O-aryl, O-alkyl, O-acyl, NH₂, NH-alkyl, NH-aryl, NH-acyl, N-(alkyl)₂, N-(aryl)₂, N-(alkyl)(aryl), PH₂, PH-alkyl, PH-aryl, PH-acyl, P-(alkyl)₂, P-(aryl)₂, P-(alkyl)(aryl), and mixtures thereof.

19. The method as defined in claim 1 wherein the hydrophilicity-modifiable connecting group comprises at least one of multivalent hetero atoms selected from the group consisting of C, N, O, S, and P; functional groups containing the hetero atoms and selected from the group consisting of SH, OH, SiCl₃, NH, and PH; saturated hydrocarbons; unsaturated hydrocarbons; substituted hydrocarbons; heterocyclic compounds; carboxylic acids; carboxylic esters; amides; nitriles; and mixtures thereof.

20. The method as defined in claim 19 wherein the hydrophilicity-modifiable connecting group functional groups comprise at least one of NH₂, NH-alkyl, NH-aryl, N-(alkyl)₂, N-(aryl)₂, N-(alkyl)(aryl), PH₂, PH-alkyl, PH-aryl, P-(alkyl)₂, P-(aryl)₂, P-(alkyl)(aryl), pyridine, and mixtures thereof.

21. A method of forming a crossed wire molecular device comprising a plurality of bottom electrodes, a plurality of top electrodes crossing the bottom electrodes at a non-zero angle, and a molecular layer comprising an organic molecule having at least one molecular switching moiety, the molecular layer operatively disposed in at least one junction formed where one electrode crosses another electrode, the method comprising:
adjusting pH of an aqueous environment comprising the organic molecule with the at least one molecular switching moiety, the moiety having a hydrophilicity-modifiable connecting group attached to one end of the moiety, and a hydrophilicity-non-modifiable connecting group attached to an opposed end of the moiety, the pH adjusting thereby transforming the hydrophilicity-modifiable connecting group to a temporary end group, wherein the temporary end group is more hydrophilic than the hydrophilicity-modifiable connecting group and the hydrophilicity-non-modifiable connecting group;
forming a Langmuir-Blodgett (LB) film of the molecule on at least one of a water/solvent interface and a water/air interface;
re-adjusting the pH of the aqueous environment so as to transform the temporary end group back to the hydrophilicity-modifiable connecting group;
passing one of the plurality of bottom electrodes through the Langmuir-Blodgett film to form the molecular layer chemically bonded, via the hydrophilicity-modifiable connecting group, on a surface of the one of the plurality of bottom electrodes; and
forming one of the plurality of top electrodes, crossing the one of the plurality of bottom electrodes at the non-zero angle, thereby forming the at least one junction therebetween, wherein the molecular layer is chemically bonded, via the hydrophilicity-non-modifiable connecting group, on a surface of the one of the plurality of top electrodes;
wherein the difference in hydrophilicity between the temporary end group and the hydrophilicity-non-modifiable connecting group causes formation of a substantially well-oriented, uniform LB film at the at least one of the water/solvent interface and the water/air interface.

22. The method as defined in claim 21 wherein the temporary end group orients the molecule such that the temporary end group preferentially resides at the at least one of a water/solvent interface and a water/air interface during the LB film formation.

23. The method as defined in claim 21 wherein the temporary end group is an ion pair.

24. The method as defined in claim 23 wherein the ion pair comprises H⁺X⁻, wherein X— is at least one of Br⁻, Cl⁻, I⁻, CH₃CO₂⁻, HCO₂⁻, NO₃⁻, H₂PO₄⁻, HPO₄²⁻, HSO₄⁻, SO₄²⁻, other organic acids, and mixtures thereof.

25. The method as defined in claim 21 wherein the solvent is at least one of water, organic solvents, and mixtures thereof.

26. The method as defined in claim 21 wherein the molecular switching moiety is at least one of an optically switchable molecular functional unit and an electrically switchable molecular functional unit.

27. The method as defined in claim 26 wherein the molecular switching moiety comprises saturated hydrocarbons, unsaturated hydrocarbons, substituted hydrocarbons, heterocyclic systems, organometallic complex systems, and mixtures thereof.

28. The method as defined in claim 26 wherein the switching moiety comprises at least one of a moiety that, in the presence of an electric field, undergoes at least one of oxidation and reduction; and a moiety that, in the presence of an electric field, experiences a band gap change.

29. The method as defined in claim 28 wherein the switching moiety undergoes at least one of oxidation and reduction, and comprises at least one of rotaxanes, pseudo-rotaxanes, catenanes, and mixtures thereof.

30. The method as defined in claim 28 wherein the switching moiety experiences a band gap change of a type comprising:
at least one of molecular conformation change and an isomerization;
change of extended conjugation via chemical bonding change to change the band gap;
at least one of molecular folding and stretching; and
combinations thereof.

31. The method as defined in claim 30 wherein the changing of extended conjugation via chemical bonding change to change the band gap is accomplished by at least one of:
charge separation or recombination accompanied by increasing or decreasing band localization; and
change of extended conjugation via charge separation or recombination and π-bond breaking or formation.

32. The method as defined in claim 21 wherein the hydrophilicity-non-modifiable connecting group comprises at least one of multivalent hetero atoms selected from the group consisting of C, N, O, S, and P; functional groups containing the hetero atoms and selected from the group consisting of SH, OH, SiCl₃, NH, and PH; saturated hydrocarbons; unsaturated hydrocarbons; substituted hydrocarbons; heterocyclic compounds; carboxylic acids; carboxylic esters; amides; nitrites; and mixtures thereof.

33. The method as defined in claim 32 wherein the hydrophilicity-non-modifiable connecting group functional groups comprise at least one of S-alkyl, S-aryl, S—S-alkyl, S—S-aryl, S-acyl, O-aryl, O-alkyl, O-acyl, NH₂, NH-alkyl, NH-aryl, NH-acyl, N-(alkyl)₂, N-(aryl)₂, N-(alkyl)(aryl), PH₂, PH-alkyl, PH-aryl, PH-acyl, P-(alkyl)₂, P-(aryl)₂, P-(alkyl)(aryl), and mixtures thereof.

34. The method as defined in claim 21 wherein the hydrophilicity-modifiable connecting group comprises at least one of multivalent hetero atoms selected from the group consisting of C, N, O, S, and P; functional groups containing the hetero atoms and selected from the group consisting of SH, OH, SiCl₃, NH, and PH; saturated hydrocarbons; unsaturated hydrocarbons; substituted hydrocarbons; heterocyclic compounds; carboxylic acids; carboxylic esters; amides; nitrites; and mixtures thereof.

35. The method as defined in claim 34 wherein the hydrophilicity-modifiable connecting group functional groups comprise at least one of NH₂, NH-alkyl, NH-aryl, N-(alkyl)₂, N-(aryl)₂, N-(alkyl)(aryl), PH₂, PH-alkyl, PH-aryl, P-(alkyl)₂, P-(aryl)₂, P-(alkyl)(aryl), pyridine, and mixtures thereof.

36. The method as defined in claim 21, further comprising:
attaching a temporary protecting group to the hydrophilicity-non-modifiable connecting group prior to adjusting pH of the aqueous environment; and
removing the temporary protecting group prior to chemically bonding the hydrophilicity-non-modifiable connecting group on the surface of the one of the plurality of top electrodes.

37. The method as defined in claim 36 wherein the temporary protecting group is hydrophobic.

38. A molecule for Langmuir-Blodgett (LB) deposition of a molecular layer, the molecule comprising:
at least one switching moiety;
a hydrophilicity-modifiable connecting group attached to one end of the moiety; and
a hydrophilicity-non-modifiable connecting group attached to an opposed end of the moiety;
wherein the hydrophilicity-modifiable connecting group is transformable to a temporary end group upon adjustment in pH of an aqueous environment in which the molecule resides, wherein the temporary end group is more hydrophilic than the hydrophilicity-modifiable connecting group and the hydrophilicity-non-modifiable connecting group, and wherein the difference in hydrophilicity between the temporary end group and the hydrophilicity-non-modifiable connecting group causes formation of a substantially well-oriented, uniform LB film at at least one of a water/solvent interface and a water/air interface.

39. The molecule as defined in claim 38 wherein the temporary end group orients the molecule such that the temporary end group preferentially resides at the at least one of a water/solvent interface and a water/air interface during the LB film formation.

40. The molecule as defined in claim 38 wherein the temporary end group is an ion pair comprising H⁺X⁻, wherein X— is at least one of Br⁻, Cl⁻, I⁻, CH₃CO₂⁻, HCO₂⁻, NO₃⁻, H₂PO₄⁻, HPO₄²⁻, HSO₄⁻, SO₄²⁻, other organic acids, and mixtures thereof.

41. The molecule as defined in claim 38 wherein the molecule is an organic molecule and wherein the switching moiety is at least one of an optically switchable molecular functional unit and an electrically switchable molecular functional unit.

42. The molecule as defined in claim 41 wherein the switching moiety comprises saturated hydrocarbons, unsaturated hydrocarbons, substituted hydrocarbons, heterocyclic systems, organometallic complex systems, and mixtures thereof.

43. The molecule as defined in claim 41 wherein the switching moiety comprises at least one of a moiety that, in the presence of an electric field, undergoes at least one of oxidation and reduction; and a moiety that, in the presence of an electric field, experiences a band gap change.

44. The molecule as defined in claim 43 wherein the switching moiety undergoes at least one of oxidation and reduction, and comprises at least one of rotaxanes, pseudo-rotaxanes, catenanes, and mixtures thereof.

45. The molecule as defined in claim 43 wherein the switching moiety experiences a band gap change of a type comprising:
at least one of molecular conformation change and an isomerization;
change of extended conjugation via chemical bonding change to change the band gap;
at least one of molecular folding and stretching; and
combinations thereof.

46. The molecule as defined in claim 45 wherein the changing of extended conjugation via chemical bonding change to change the band gap is accomplished by at least one of:
charge separation or recombination accompanied by increasing or decreasing band localization; and
change of extended conjugation via charge separation or recombination and π-bond breaking or formation.

47. The molecule as defined in claim 41 wherein one of the hydrophilicity-modifiable connecting group and the hydrophilicity-non-modifiable connecting group is a connecting unit between the organic molecule and a substrate, and wherein the other of the hydrophilicity-non-modifiable connecting group and the hydrophilicity-modifiable connecting group is a connecting unit between the organic molecule and an other substrate.

48. The molecule as defined in claim 47 wherein at least one of the substrate and the other substrate comprises an electrode of a crossed-wire device.

49. The molecule as defined in claim 48 wherein the electrode comprises at least one of a bottom electrode and a top electrode.

50. The molecule as defined in claim 47 wherein the hydrophilicity-modifiable connecting group is a connecting unit between the organic molecule and the substrate, and wherein the substrate is a bottom electrode.

51. The molecule as defined in claim 50 wherein the hydrophilicity-non-modifiable connecting group is a connecting unit between the organic molecule and the other substrate, and wherein the other substrate is a top electrode.

52. The molecule as defined in claim 38 wherein the hydrophilicity-non-modifiable connecting group comprises at least one of multivalent hetero atoms selected from the group consisting of C, N, O, S, and P; functional groups containing the hetero atoms and selected from the group consisting of SH, OH, SiCl₃, NH, and PH; saturated hydrocarbons; unsaturated hydrocarbons; substituted hydrocarbons; heterocyclic compounds; carboxylic acids; carboxylic esters; amides; nitriles; and mixtures thereof.

53. The molecule as defined in claim 52 wherein the hydrophilicity-non-modifiable connecting group functional groups comprise at least one of S-alkyl, S-aryl, S—S-alkyl, S—S-aryl, S-acyl, O-aryl, O-alkyl, O-acyl, NH₂, NH-alkyl, NH-aryl, NH-acyl, N-(alkyl)₂, N-(aryl)₂, N-(alkyl)(aryl), PH₂, PH-alkyl, PH-aryl, PH-acyl, P-(alkyl)₂, P-(aryl)₂, P-(alkyl)(aryl), and mixtures thereof.

54. The molecule as defined in claim 38 wherein the hydrophilicity-modifiable connecting group comprises at least one of multivalent hetero atoms selected from the group consisting of C, N, O, S, and P; functional groups containing the hetero atoms and selected from the group consisting of SH, OH, SiCl₃, NH, and PH; saturated hydrocarbons; unsaturated hydrocarbons; substituted hydrocarbons; heterocyclic compounds; carboxylic acids; carboxylic esters;
amides; nitriles; and mixtures thereof.

55. The molecule as defined in claim 54 wherein the hydrophilicity-modifiable connecting group functional groups comprise at least one of NH₂, NH-alkyl, NH-aryl, N-(alkyl)₂, N-(aryl)₂, N-(alkyl)(aryl), PH₂, PH-alkyl, PH-aryl, P-(alkyl)₂, P-(aryl)₂, P-(alkyl)(aryl), pyridine, and mixtures thereof.

56. A molecular switching device, comprising:
at least one bottom electrode;
at least one top electrode, the top electrode crossing the bottom electrode at a non-zero angle, thereby forming a junction; and
a molecular layer operatively disposed in the junction, the molecular layer comprising:
at least one molecule having at least one switching moiety; a hydrophilicity-modifiable connecting group attached to one end of the moiety; and a hydrophilicity-non-modifiable connecting group attached to an opposed end of the moiety; wherein the hydrophilicity-modifiable connecting group is transformable to a temporary end group upon adjustment in pH of an aqueous environment in which the molecule resides, wherein the temporary end group is more hydrophilic than the hydrophilicity-modifiable connecting group and the hydrophilicity-non-modifiable connecting group, and wherein the difference in hydrophilicity between the temporary end group and the hydrophilicity-non-modifiable connecting group causes formation of a substantially well-oriented, uniform Langmuir-Blodgett (LB) film at at least one of a water/solvent interface and a water/air interface;
wherein, upon re-adjustment of the pH of the aqueous environment and consequent transformation of the temporary end group back to the hydrophilicity-modifiable connecting group, the molecular layer is chemically bonded during an LB process, via the hydrophilicity-modifiable connecting group, on a surface of the at least one bottom electrode, and the molecular layer is chemically bonded, via the hydrophilicity-non-modifiable connecting group, on a surface of the at least one top electrode.
